(19) United States
(12) Patent Application Publication
(10) Pub. No.: US 2018/0174992 A1
(43) Pub. Date: Jun. 21, 2018

(54) SEMICONDUCTOR DEVICE WITH COPPER MIGRATION STOPPING OF A REDISTRIBUTION LAYER

(71) Applicant: Chengdu Monolithic Power Systems Co., Ltd., Chengdu (CN)

(72) Inventors: Fayou Yin, Chengdu (CN); Zeqiang Yao, Santa Clara, CA (US); Ming Xiao, Wuxi (CN); Heng Li, Chengdu (CN)

(21) Appl. No.: 15/839,818

(22) Filed: Dec. 12, 2017

(30) Foreign Application Priority Data
Dec. 21, 2016 (CN) 201611190566.0

(51) Int. Cl. H01L 23/00; H01L 23/31; H01L 21/56

(52) U.S. Cl. CPC H01L 24/13; H01L 2224/11849; H01L 21/56; H01L 24/11; H01L 24/05; H01L 24/03; H01L 2224/13147; H01L 2224/13111; H01L 2924/14; H01L 2224/02372; H01L 2224/0235; H01L 2224/02381; H01L 2224/02331; H01L 2224/024; H01L 2924/07025; H01L 2224/0239; H01L 2924/0105; H01L 2924/01079; H01L 2924/01082; H01L 2924/01078; H01L 2924/01028; H01L 2924/01046; H01L 2924/01022; H01L 2224/0231; H01L 2224/13082; H01L 2224/13024; H01L 2224/13017; H01L 2224/11019; H01L 2924/066; H01L 2924/2064; H01L 2924/01029; H01L 2224/1146; H01L 23/3171

(57) ABSTRACT

A semiconductor device having a redistribution layer and a first coating layer. The redistribution layer is formed on a passivation layer of the semiconductor device and has sidewalls and a top surface. The first coating layer covers the sidewalls and the top surface of the redistribution layer. The first coating layer is conductive so that through a conductive bump coupled to the first coating layer, an external circuit is coupled to an electrical terminal of an integrated circuit of the semiconductor device. The first coating layer has sidewalls and a top surface. A second coating layer covers the sidewalls and a part of the top surface of the first coating layer and a part of the passivation layer.

### CROSS REFERENCE

This application claims the benefit of CN application No. 201611190566.0, filed on Dec. 21, 2016, and incorporated herein by reference.

### FIELD OF THE INVENTION

This disclosure generally relates to a semiconductor device and more particularly but not exclusively to a structure that connects an integrated circuit to an external circuit.

### BACKGROUND OF THE INVENTION

It is a significant trend of designing a semiconductor device to have smaller size with increasing density. To this end, in terms of packaging the semiconductor, the flip chip package approach is more and more popularly used instead of the traditional wire bonding solution.

In the flip chip packaging approach, conductive bumps (solder balls or copper pillars with solder bumps etc.) are used to couple electrical terminals of a semiconductor device to a package lead frame, a package substrate or a printed circuit board. The semiconductor device may have a plurality of electrical terminals for receiving, sending or transferring signals.

As the size of a semiconductor device continues to decrease and the density of the semiconductor device continues to increase, the layout of metal traces is complex and the pitch between two adjacent metal traces is decreasing.

Thus, migration phenomenon is easy to occur between adjacent metal traces coupled to different electrical terminals, especially when the semiconductor device works in a high temperature and/or a high humidity condition. Migration phenomenon may cause two adjacent metal traces coupled to different electrical terminals to be electrically shorted and may thus cause the failure of the semiconductor device.

In light of above description, a novel structure is required to decrease or prevent the migration phenomenon.

### SUMMARY

Embodiments of the present invention are directed to a semiconductor device. The semiconductor device, comprising: a semiconductor substrate having an integrated circuit and a metal layer, wherein the metal layer is coupled to the integrated circuit; a passivation layer on the semiconductor substrate; a plurality of vias formed in the passivation layer to expose a plurality of surfaces of the metal layer; a redistribution layer formed on a part of the passivation layer and in the plurality of vias, wherein the redistribution layer is coupled to the metal layer and has sidewalls and a top surface; and a first coating layer covering the top surface and the sidewalls of the redistribution layer, wherein the first coating layer is conductive and has sidewalls and a top surface, and wherein the top surface of the first coating layer comprises a first part and a second part.

Embodiments of the present invention are also directed to a semiconductor device. The semiconductor device, comprising: a semiconductor substrate having an integrated circuit and a metal layer, wherein the metal layer is coupled to the integrated circuit; a passivation layer on the semiconductor substrate; a first connection structure and a second connection structure, wherein each of the connection structures comprises: a plurality of vias formed in the passivation layer to expose a plurality of surfaces of the metal layer; a redistribution layer formed on a part of the passivation layer and in the plurality of vias, wherein the redistribution layer has sidewalls and a top surface; and a first coating layer covering the top surface and the sidewalls of the redistribution layer, wherein the first coating layer is conductive and has sidewalls and a top surface, and wherein the top surface of the first coating layer comprises a first part and a second part.

Embodiments of the present invention are directed to a method of manufacturing a semiconductor device. The method of manufacturing a semiconductor device, comprising: forming a passivation layer on a semiconductor substrate having a metal layer; forming a plurality of vias in the passivation layer to expose a plurality of surfaces of the metal layer; forming a redistribution layer on a part of the passivation layer and in the plurality of vias so that the redistribution layer is coupled to the metal layer, wherein the redistribution layer has sidewalls and a top surface; and forming a first coating layer on the sidewalls and the top surface of the redistribution layer, wherein the first coating layer is conductive and has sidewalls and a top surface.

With the above benefits, the novel structure of the present invention can stop migration as compared with the traditional technology, the failure or all the problems caused by the migration are thereby eliminated and the novel structure of the present invention has more reliability under high temperature and/or high humidity condition.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features.

FIG. 1 shows a cross-section of a portion of a semiconductor device 100 in accordance with an embodiment of the present invention.

FIG. 2 shows a cross-section of a portion of a semiconductor device 200 in accordance with an alternative embodiment of the present invention.

FIG. 3 shows a cross-section of a portion of a semiconductor device 300 in accordance with another alternative embodiment of the present invention.

FIGS. 4-16 show cross-sections of a flow diagram of manufacturing the semiconductor device 100 of FIG. 1 in accordance with an embodiment of the present invention.

The use of the same reference label in different drawings indicates the same or like components or structures with substantially the same functions for the sake of simplicity.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the term “coupled” as used herein, is defined as directly or indirectly connected in an electrical or non-electrical manner. The terms “a”, “an” and “the” include plural reference and the term “in” includes “in” and “on”. The phrase “in one embodiment” as used herein does not necessarily refer to the same embodiment, although it may. The term “or” is an inclusive “or” operator, and is equivalent to the term “and/or” herein, unless the context clearly dictates otherwise. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. Those skilled in the art should understand that the meanings of the terms identified above do not necessarily limit the terms, but merely provide illustrative examples for the terms.

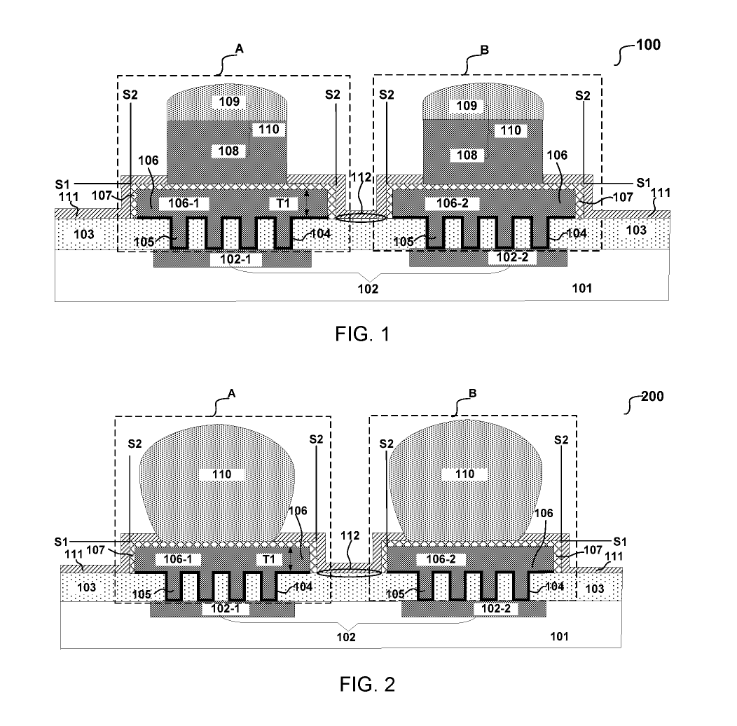

FIG. 1 shows a cross-section of a portion of a semiconductor device 100 in accordance with an embodiment of the present invention. The semiconductor device 100 comprises a semiconductor substrate 101. An integrated circuit (not shown in FIG. 1) that may comprise a DC-DC convertor, a micro controller or other active or passive circuit elements may be manufactured in the semiconductor substrate 101. The semiconductor substrate 101 may further comprise a metal layer 102 formed in an upper portion of the semiconductor substrate 101 and coupled to the integrated circuit. One skilled in the relevant art should recognize that the metal layer 102 may comprise a single metal layer or multi-metal layers. In the embodiments of multi-metal layers, herein the metal layer 102 refers to the top layer of the multi-metal layers. In an embodiment, the metal layer 102 comprises aluminum. One skilled in the relevant art should understand, the integrated circuit fabricated in the semiconductor substrate 101 may comprise a plurality of electrical terminals coupled to different signals respectively. In such embodiments, the metal layer 102 comprises many different routings (such as 102-1 and 102-2 shown in FIG. 1) to couple each of the electrical terminals of the integrated circuit to an external electrical circuit, such as a printed circuit board. In an embodiment, the semiconductor substrate 101 may further comprise inter-layer dielectric layers.

In the example of FIG. 1, the semiconductor device 100 further comprises a passivation layer 103 formed on the semiconductor substrate 101. In an embodiment, the passivation layer 103 comprises silicon oxide and/or silicon nitride. In an embodiment, the passivation layer 103 comprises a stack of silicon oxide and silicon nitride, with the silicon oxide being formed on the semiconductor substrate 101 and the silicon nitride being formed on the silicon oxide.

Referring to the exemplary embodiment shown in FIG. 1, the semiconductor device 100 further comprises a plurality of vias 105, wherein the plurality of vias 105 are formed in the passivation layer 103 to expose a plurality of surfaces of the metal layer 102 so that the metal layer 102 is electrically coupled to a redistribution layer 106 which will be described later. In an embodiment, the plurality of vias 105 is located in the portion of the passivation layer 103 on the metal layer 102. In an embodiment, each of the vias 105 may have a different shape and size, such as a rectangle with 3 μm*3 μm or a rectangle with 6 μm*3 μm. One skilled in the relevant art should understand, although the plurality of vias 105 are illustrated in the embodiment of FIG. 1, it should be understood the illustration and description in this disclosure are not intended to be limiting and exclusive. One skilled in the relevant art should understand that a single via 105 may be formed in the semiconductor device 100. In the embodiment of FIG. 1, the semiconductor device 100 further comprises a redistribution layer 106 formed on a part of the passivation layer 103 and in the plurality of vias 105. The redistribution layer 106 has a top surface and sidewalls. In an embodiment, the redistribution layer 106 may comprises copper and has a thickness of T1, which is determined by design specification. In an embodiment, T1 is in a range of 1 μm to 30 μm. In another embodiment, T1 is in a range of 5 μm to 10 μm.

Referring to the exemplary embodiment shown in FIG. 1, the semiconductor device 100 may further comprise a seed layer 104, wherein the seed layer 104 may be located between the passivation layer 103 and the redistribution layer 106 and on the plurality of surfaces of the metal layer 102. The seed layer 104 can provide a good adhesion between the redistribution layer 106 and the passivation layer 103 and a good adhesion between the redistribution layer 106 and the metal layer 102. The seed layer 104 can be further used as a diffusion barrier layer to prevent the metal diffusion between the redistribution layer 106 and the metal layer 102 and the metal diffusion between the redistribution layer 106 and the passivation layer 103. In an embodiment, the seed layer 104 comprises copper.

In the embodiment of FIG. 1, the semiconductor device 100 further comprises a first coating layer 107 covering the top surface and the sidewalls of the redistribution layer 106. The first coating layer 107 has a top surface S1 and sidewalls S2. In an embodiment, the first coating layer 107 comprises tin, in an alternative embodiment, the first coating layer 107 comprises gold, lead, platinum, nickel, palladium or titanium. In an embodiment, the first coating layer 107 is formed by Chemical Plating. In another embodiment, the tin ions are deposited on the sidewalls and the top surface of the redistribution layer 106 by Chemical Plating to form the first coating layer 107. In other embodiments, the first coating layer 107 can be formed by gold, lead, platinum, nickel, palladium or titanium Chemical Plating. In the embodiment shown in FIG. 1, the thickness of the first coating layer 107 is determined by design specification. In an embodiment, the thickness of the first coating layer 107 is in a range of 200 Å to 10000 Å. In another embodiment, the thickness of the first coating layer 107 is in a range of 1000 Å to 3000 Å.

Continuing the introduction of FIG. 1, the semiconductor device 100 further comprises a conductive bump 110, which is formed on a part of the top surface S1 of the first coating layer 107 and coupled to the first coating layer 107. The conductive bump 110 comprises a copper pillar 108 and a solder bump 109, with the copper pillar 108 being formed on the part of the top surface S1 of the first coating layer 107 and coupled to the first coating layer 107, and the solder bump 109 being formed on the copper pillar 108 and coupled to the copper pillar 108. It should be known that, herein the solder bump 109 comprises tin or tin alloy.

Still referring to the embodiment of FIG. 1, the semiconductor device 100 further comprises a second coating layer 111 formed on the sidewalls S2 and the remaining part of the top surface S1 of the first coating layer 107 and the remaining part of the passivation layer 103 (the region of the passivation layer 103 uncovered by the redistribution layer 106 or the first coating layer 107). In an embodiment, the second coating layer 111 may comprise polyimide. In another embodiment, the second coating layer 111 may comprise PBO (Poly-p-Phenylene Benzobisoxazole). In an embodiment, the thickness of the second coating layer 111 is in a range of 1 μm to 20 μm. In another embodiment, the thickness of the second coating layer 111 is in a range of 5 μm to 10 μm.

In the embodiment of FIG. 1, the semiconductor device 100 comprises the substrate layer 101 having the integrated circuit (not shown in FIG. 1) and the metal layer 102, the passivation layer 103 formed on the substrate layer 101, a first connection structure A and a second connection structure B and the second coating layer 111.

Each of the connection structures A and B comprises the plurality of vias 105, the redistribution layer 106 and the first coating layer 107. Wherein the plurality of vias 105 are formed in the passivation layer 103 to expose a plurality of surfaces of the metal layer 102. The redistribution layer 106 is formed on a part of the passivation layer 103 and in the plurality of vias 105. The redistribution layer 106 has sidewalls and a top surface which are covered by the first coating layer 107. In an embodiment, the first coating layer 107 has the top surface S1 and the sidewalls S2. In an embodiment, the first coating layer 107 comprises tin. In another embodiment, the first coating layer 107 comprises gold, lead, platinum, nicked, palladium or titanium. In an embodiment, the first coating layer 107 is formed by Chemical Plating. In another embodiment, the tin ions are deposited on the sidewalls and the top surface of the redistribution layer 106 by Chemical Plating to form the first coating layer 107. In other embodiments, the first coating layer 107 can be formed by gold, lead, platinum, nickel, palladium or titanium Chemical Plating. In the embodiment shown in FIG. 1, the thickness of the first coating layer 107 is determined by design specification. In an embodiment, the thickness of the first coating layer 107 is in a range of 200 Å to 10000 Å. In another embodiment, the thickness of the first coating layer 107 is in a range of 1000 Å to 3000 Å.

Still referring FIG. 1, each of the connection structures A and B may further comprise the conductive bump 110 formed on the part of the top surface S1 of the first coating layer 107 and coupled to the first coating layer 107. The conductive bump 110 comprises the copper pillar 108 and the solder bump 109, with the copper pillar 108 being formed on the part of the top surface S1 of the first coating layer 107 and coupled to the first coating layer 107, and the solder bump 109 being formed on the copper pillar 108 and coupled to the copper pillar 108.

In the embodiment of FIG. 1, the semiconductor device 100 further comprises the second coating layer 111 formed on the sidewalls S2 and the remaining part of the top surface S1 of the first coating layer 107 and the remaining part of the passivation layer 103 (the region of the passivation layer 103 uncovered by the redistribution layer 106 or the first coating layer 107). In an embodiment, the second coating layer 111 may comprise polyimide. In another embodiment, the second coating layer 111 may comprise PBO (Poly-p-Phenylene Benzobisoxazole). In an embodiment, the thickness of the second coating layer 111 is in a range of 1 μm to 20 μm. In another embodiment, the thickness of the second coating layer 111 is in a range of 5 μm to 10 μm.

Still referring to FIG. 1, in some embodiments, the redistribution layer 106 comprises different redistribution routings (such as 106-1 and 106-2 shown in FIG. 1), which are coupled to different metal routings (such as 102-1 and 102-2 shown in FIG. 1) for connecting the plurality of the electrical terminals of the semiconductor device 100 to external circuits. The semiconductor device 100 will be molded by a molding compound (not shown in FIG. 1) in a package process. In the traditional technology, the different redistribution routings 106-1 and 106-2 are easy to be electrically shorted due to the ion migration caused by electric field. For example, the redistribution layer 106 has different redistribution routings (such as redistribution routing 106-1 and redistribution routing 106-2 shown in FIG. 1) and these redistribution routings comprise copper, thus the redistribution routing 106-1 and the redistribution routing 106-2 are easy to be electrically shorted due to the copper migration. In this application, the first coating layer 107 is formed on the top surface and the sidewalls of the redistribution layer 106, the first coating layer 107 can prevent the migration phenomenon effectively.

In the traditional technology, in the process of package, such as in the process of forming the conductive bumps 110 or reflowing the conductive bumps 110, the conductive bumps 110 coupled to different electrical terminals are easy to be electrically shorted due to the deformation or the splashing-down of the conductive bumps 110. Redistribution routing 106-1 and redistribution routing 106-2 are easy to be electrically shorted due to the splashing-down of the conductive bumps 110 into the pitches (region 112 shown in FIG. 1) between the two redistribution routings. In this application, the semiconductor device 100 with the second coating layer 111 can prevent this short circuit phenomenon effectively for the second coating layer 111 can insulate each redistribution routings.

FIG. 2 shows a cross-section of a portion of a semiconductor device 200 in accordance with another alternative embodiment of the present invention. Compared with the semiconductor device 100 of FIG. 1, the semiconductor device 200 has another structure of the conductive bump 110. This structure of the conductive bump 110 comprises a solder ball, wherein the solder ball comprises tin or tin alloy.

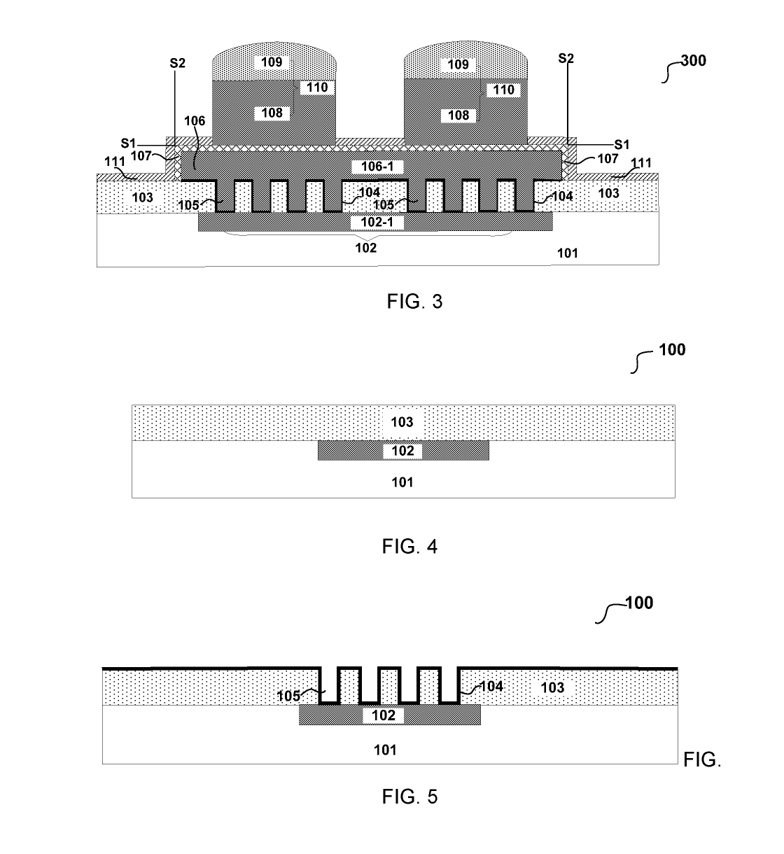

FIG. 3 shows a cross-section of a portion of a semiconductor device 300 in accordance with an alternative embodiment of the present invention. The metal routing 102-1 of the metal layer 102 is coupled to two conductive bumps 110. It should be known that, in other embodiments, the routing 102-1 may be coupled to more than two conductive bumps 110, the two conductive bumps 110 in FIG. 3 are just for example.

FIGS. 4-16 show cross-sections of a flow diagram of manufacturing the semiconductor device 100 of FIG. 1 in accordance with an embodiment of the present invention. For the sake of simplicity, only one connection structure is illustrated in FIGS. 4-16, but it should be understood that a plurality of connection structures may be formed in semiconductor device 100.

Firstly referring to FIG. 4, a metal layer 102 are formed in a semiconductor substrate 101, wherein the metal layer 102 is coupled to an integrated circuit.

In an embodiment, the metal layer 102 may comprise a single metal layer or multi-metal layers. In the embodiments of multi-metal layers, herein the metal layer 102 refers to the top layer of the multi-metal layers. In an embodiment, the metal layer 102 comprises aluminum. In the embodiment of FIG. 4, a passivation layer 103 is formed on the semiconductor substrate 101. In an embodiment, the passivation layer 103 may comprise a stack of silicon oxide and silicon nitride, with the silicon oxide being formed on the semiconductor substrate 101, and silicon nitride being formed on the silicon oxide.

Subsequently, referring to FIG. 5, a plurality of vias 105 are formed in the passivation layer 103 to expose a plurality of surfaces of the metal layer 102. In an embodiment, each of the vias 105 may have a different shape and size, such as a rectangle with 3 μm*3 μm or a rectangle with 6 μm*3 μm. Then a seed layer 104 is formed on the surface of the passivation layer 103 and on the plurality surfaces of the metal layer 102 that are exposed by the plurality of vias 105. In an embodiment, the seed layer 104 is formed by sputtering.

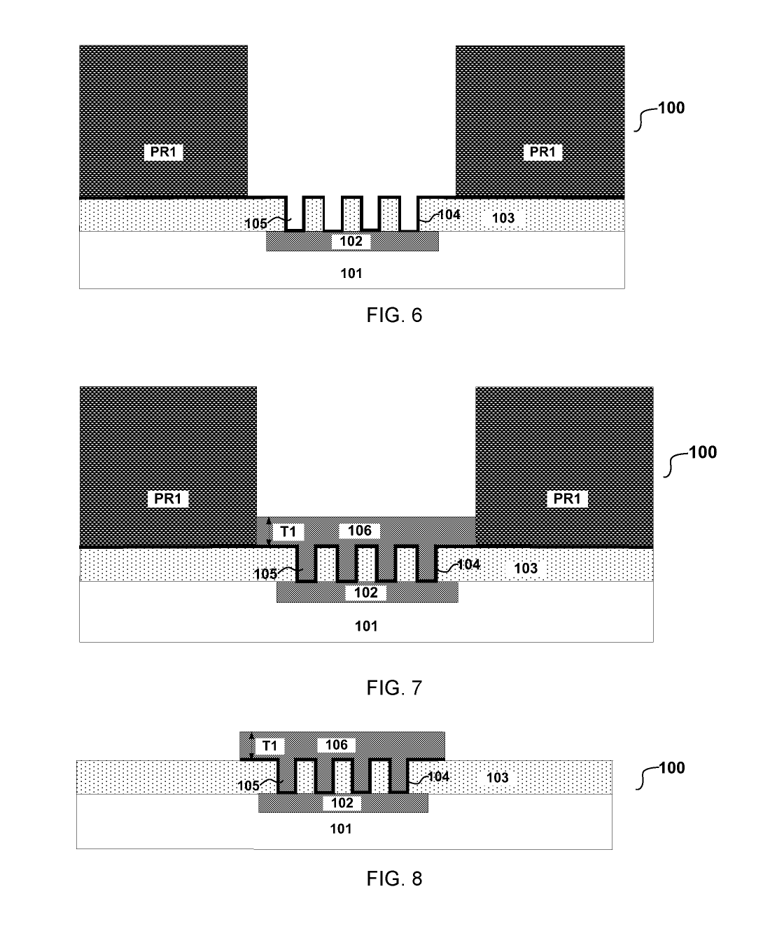

In subsequence, referring to FIG. 6, a first plating mask PR1 is formed on the seed layer 104 to define a region where a redistribution layer 106 is to be formed, wherein the first plating mask PR1 comprises photosensitive material, such as photo resist material.

Then referring to FIG. 7, the redistribution layer 106 is formed at the shielding of the first plating mask PR1. In an embodiment, the redistribution layer 106 is formed by copper electroplating. In an embodiment, the redistribution layer 106 has a thickness of T1, which is determined by design specification. In an embodiment, T1 is in a range of 1 μm to 30 μm, in another embodiment, T1 is in a range of 5 μm to 10 μm.

Then referring to FIG. 8, the first plating mask PR1 is removed. In an embodiment, the first plating mask PR1 is removed in a photosensitive material (such as a photo resist) strip process. After removing the first plating mask PR1, the region of the seed layer 104 which is not covered by the redistribution layer 106 is removed. In an embodiment, the region of the seed layer 104 which is not covered by the redistribution layer 106 is removed by etching.

One skilled in the relevant art should recognize that, in some embodiments, the step of forming the seed layer 104 as described above is selectable, and can be omitted according the specific application. In such embodiments, the first plating mask PR1 and the redistribution layer 106 can be formed on the passivation layer 103. Therefore, in such an embodiment, there is no need of the step of removing the seed layer 104.

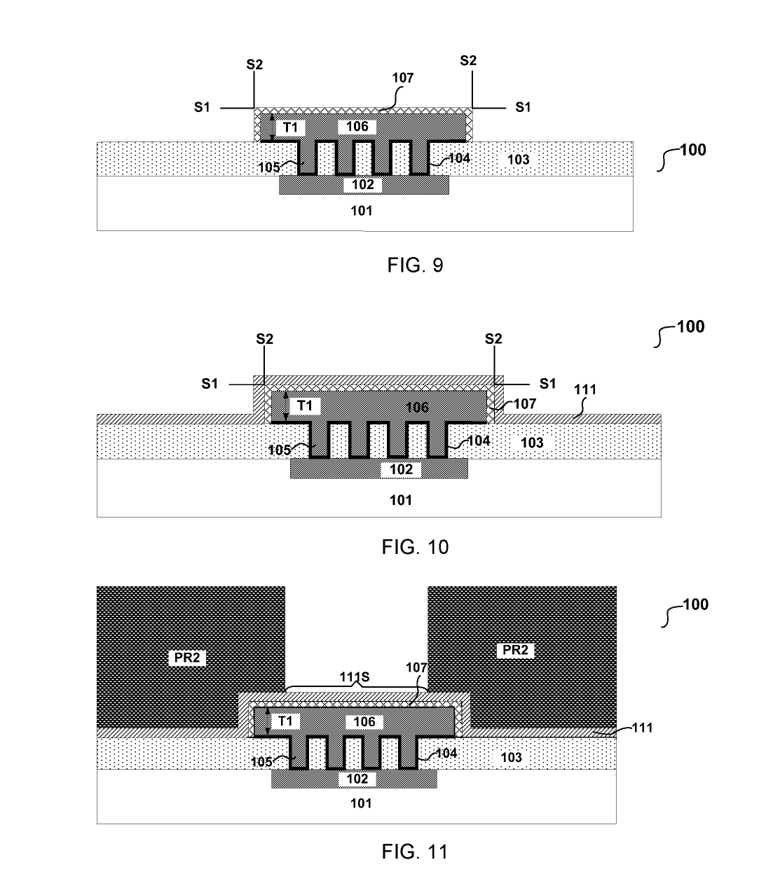

Then referring to FIG. 9, a first coating layer 107 is formed on the top surface and the sidewalls of the redistribution layer 106 by the Chemical Plating method. The first coating layer 107 has a top surface S1 and the sidewalls S2. In an embodiment, the first coating layer 107 comprises tin. In another embodiment, the first coating layer 107 comprises gold, lead, platinum, nickel, palladium or titanium. In an embodiment, the thickness of the first coating layer 107 is determined by the practical specification. In an embodiment, the thickness of the first coating layer 107 is in a range from 200 Å to 10000 Å. In another embodiment, the thickness of the first coating layer is in a range from 1000 Å to 3000 Å.

Referring to FIG. 10, a second coating layer 111 is formed on the sidewalls S2 and the top surface S1 of the first coating layer 107 and the remaining part of the passivation layer 103 (the region of the passivation layer 103 uncovered by the redistribution layer 106 or the first coating layer 107). In an embodiment, the second coating layer 111 comprises polyimide or PBO (Poly-p-phenyleneBenzobisoxazole).

Then referring to FIG. 11, a second plating mask PR2 that may comprise a photosensitive material is formed on the second coating layer 111 to define a region where a conductive bump 110 is to be formed. In an embodiment, the second plating mask PR2 comprises photo resist. In the embodiment of FIG. 11, the second plating mask PR2 exposes a region 111S of the second coating layer 111 to form a copper pillar 108 and covers the remaining regions of the second coating layer 111.

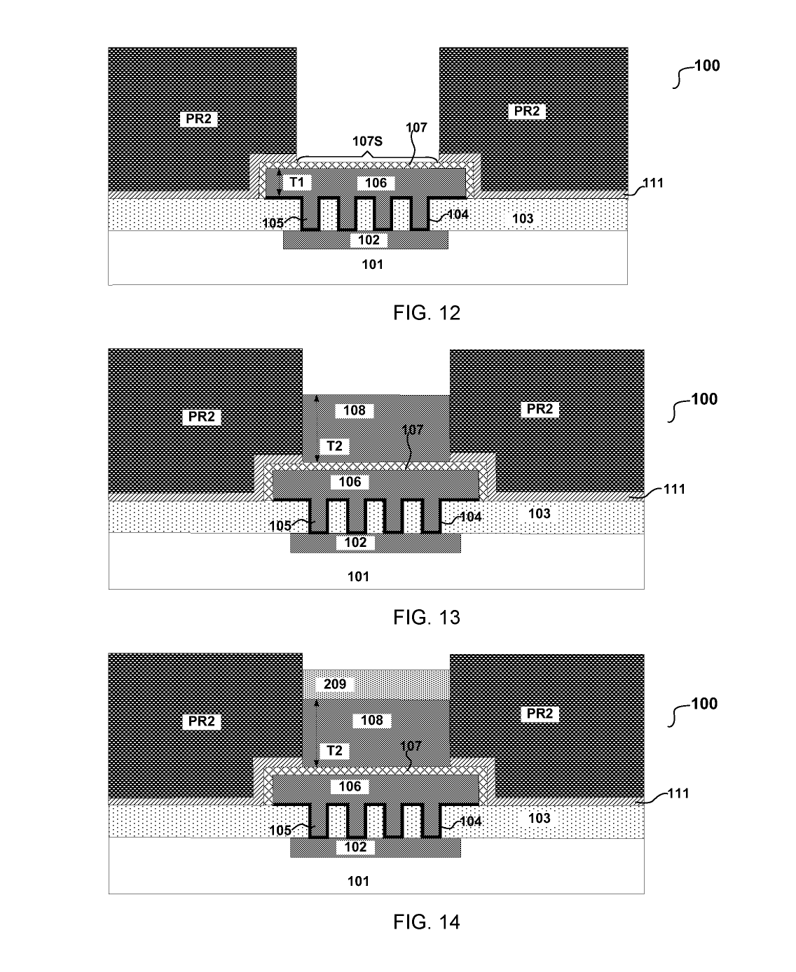

Referring to FIG. 12, the region 111S of the second coating layer 111 is etched and the surface 107S of the first coating layer 107 is exposed.

Subsequently, referring to FIG. 13˜FIG. 16, a conductive bump 110 is formed. In an embodiment, forming the conductive bump 110 may comprise: forming a copper pillar 108 at first as FIG. 13 shows and then forming a solder layer 209 on the copper pillar 108 as FIG. 14 shows. In an embodiment, the copper pillar 108 may comprise copper and has a thickness of T2, which is determined by design specification. In an embodiment, T2 is in a range of 35 μm to 65 μm, in another embodiment, T2 is in a range of 55 μm to 65 μm.

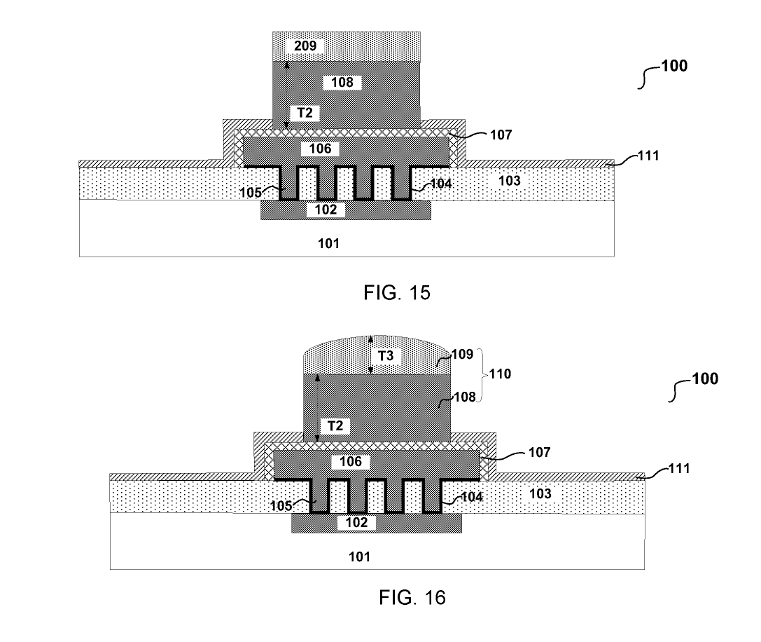

Then referring to FIG. 15, the second plating mask PR2 is removed. And then, the structure of FIG. 15 is heated. In an embodiment, the step of heating the structure of FIG. 15 may comprise a reflow process, and the reflow process may involve placing the structure of FIG. 15 in a reflow oven or other furnace so that the structure of FIG. 15 goes through a thermal profile. The heat provided in the reflow process causes the solder layer 209 to form a solder bump 109, thereby a structure of FIG. 16 is formed. The solder bump 109 may comprise tin or tin alloy, and the solder bump 109 has a thickness of T3, which is determined by design specification. In an embodiment, T3 is in a range of 10 μm to 50 μm, in another embodiment, T3 is in a range of 25 μm to 50 μm. One of ordinary skill in the art should understand that the ranges for the thickness are only examples and are not intended to limit the invention.

From the foregoing, it will be appreciated that specific embodiments of the present invention have been described herein for purposes of illustration, but that various modifications may be made without deviating from the spirit and scope of various embodiments of the present invention. Many of the elements of an embodiment may be combined with other embodiments in addition to or in lieu of the elements of the other embodiments. Accordingly, the present invention is not limited except as by the appended claims.

What is claimed is:

1. A semiconductor device, comprising:
a semiconductor substrate having an integrated circuit and a metal layer, wherein the metal layer is coupled to the integrated circuit;
a passivation layer on the semiconductor substrate;
a plurality of vias formed in the passivation layer to expose a plurality of surfaces of the metal layer;
a redistribution layer formed on a part of the passivation layer and in the plurality of vias, wherein the redistribution layer is coupled to the metal layer and has sidewalls and a top surface; and
a first coating layer covering the top surface and the sidewalls of the redistribution layer, wherein the first coating layer is conductive and has sidewalls and a top surface, and wherein the top surface of the first coating layer comprises a first part and a second part.

2. The semiconductor device of claim 1, further comprising a second coating layer covering the sidewalls and the first part of the top surface of the first coating layer and the remaining part of the passivation layer.

3. The semiconductor device of claim 2, wherein the second coating layer comprises polyimide or PBO.

4. The semiconductor device of claim 1, further comprising a conductive bump formed on the second part of the top surface of the first coating layer.

5. The semiconductor device of claim 4, wherein the conductive bump comprises:
a copper pillar formed on the second part of the top surface of the first coating layer; and
a solder bump formed on the copper pillar, wherein the solder bump comprises tin or tin alloy.

6. The semiconductor device of claim 4, wherein the conductive bump comprises a solder ball formed on the second part of the top surface of the first coating layer, wherein the solder ball comprises tin or tin alloy.

7. The semiconductor device of claim 1, wherein the first coating layer comprises tin, gold, lead, platinum, nickel, palladium or titanium.

8. The semiconductor device of claim 1, wherein the thickness of the first coating layer is in a range of 200 Å to 10000 Å.

9. A semiconductor device, comprising:
a semiconductor substrate having an integrated circuit and a metal layer, wherein the metal layer is coupled to the integrated circuit;
a passivation layer on the semiconductor substrate; and
a first connection structure and a second connection structure, wherein each of the connection structures comprises:
a plurality of vias formed in the passivation layer to expose a plurality of surfaces of the metal layer;
a redistribution layer formed on a part of the passivation layer and in the plurality of vias, wherein the redistribution layer has sidewalls and a top surface; and
a first coating layer covering the top surface and the sidewalls of the redistribution layer, wherein the first coating layer is conductive and has sidewalls and a top surface, and wherein the top surface of the first coating layer comprises a first part and a second part.

10. The semiconductor device of claim 9, further comprising a second coating layer covering the sidewalls and the first part of the top surface of the first coating layer of each connection structure and the remaining part of the passivation layer.

11. The semiconductor device of claim 10, wherein the second coating layer comprises polyimide or PBO.

12. The semiconductor device of claim 9, wherein each of the connection structures further comprises a conductive bump formed on the second part of the top surface of the first coating layer.

13. The semiconductor device of claim 12, wherein the conductive bump comprises:
a copper pillar formed on the second part of the top surface of the first coating layer; and
a solder bump formed on the copper pillar, wherein the solder bump comprises tin or tin alloy.

14. The semiconductor device of claim 9, wherein the first coating layer comprises tin, gold, lead, platinum, nickel, palladium or titanium.

15. A method of manufacturing a semiconductor device, comprising:
forming a passivation layer on a semiconductor substrate having a metal layer;
forming a plurality of vias in the passivation layer to expose a plurality of surfaces of the metal layer;
forming a redistribution layer on a part of the passivation layer and in the plurality of vias so that the redistribution layer is coupled to the metal layer, wherein the redistribution layer has sidewalls and a top surface; and
forming a first coating layer on the sidewalls and the top surface of the redistribution layer, wherein the first coating layer is conductive and has sidewalls and a top surface.

16. The method of claim 15, further comprising forming a second coating layer on the sidewalls and the top surface of the first coating layer and the remaining part of the passivation layer.

17. The method of claim 16, further comprising:
removing a portion of the second coating layer to expose a part of the top surface of the first coating layer; and
forming a conductive bump on the part of the top surface of the first coating layer.

18. The method of claim 16, wherein the second coating layer comprises polyimide or PBO.

19. The method of claim 15, wherein the first coating layer comprises tin, gold, lead, platinum, nickel, palladium or titanium.

20. The method of claim 15, wherein the first coating layer is formed by Chemical Plating.
